(19) United States
(12) Patent Application Publication
(10) Pub. No.: US 2020/0329177 A1
(43) Pub. Date: Oct. 15, 2020

(54) CAMERA AND DOCKING STATION

(71) Applicant: Opkix, Inc., Costa Mesa, CA (US)

(72) Inventors: Christopher Lawrence Greaves, Huntington Beach, CA (US); John McGuinness, Huntington Beach, CA (US); Shahin Amirpour, Huntington Beach, CA (US); Ryan Mikah Fuller, Costa Mesa, CA (US); Lane Gearle Brooks, Highland, UT (US)

(21) Appl. No.: 16/794,008

(22) Filed: Feb. 18, 2020

Related U.S. Application Data
(60) Provisional application No. 62/807,747, filed on Feb. 19, 2019.

(51) Int. Cl. H04N 5/225; G06F 1/16; H05K 1/14

(52) U.S. Cl. CPC H04N 5/2252; H05K 1/148; G06F 1/1632

(57) ABSTRACT

A camera system can include a portable camera and a docking station for storing the portable camera, re-charging the portable camera, or transferring image data from the portable camera. The portable camera can be removably coupled with the docking station with any of multiple different rotational orientations. A portable camera can include a unibody housing, a foldable printed circuit board assembly, and a battery. The foldable printed circuit board assembly can be folded at least partially around the battery. A method of assembling a portable camera can include providing a unibody housing. The unibody housing can have one or more sidewalls and an open end. One or more components of the portable camera can be inserted through the open end into the unibody housing.

### INCORPORATION BY REFERENCE TO ANY PRIORITY APPLICATIONS

This application claims priority to U.S. Provisional Patent Application No. 62/807,747, filed Feb. 19, 2019, and entitled “CAMERA AND DOCKING STATION.” This and any other application for which a foreign or domestic priority claim is identified in the Application Data Sheet, as filed with the present application, are hereby incorporated by reference under 37 CFR 1.57.

### BACKGROUND

### Field

This disclosure relates to a portable camera and docking station.

### Description of the Related Art

Portable computing devices (PCD), such as smartphones, have become ubiquitous among industrialized populations. Many PCDs include integrated cameras. However, PCD-based cameras are not well-suited to some image capture applications. For example, the size, shape, weight, structural strength, complicated operation, and/or cost of a PCD may restrict or discourage its use for certain image capture applications, such as those involving spontaneous moments, sports, etc., where a less bulky and/or simpler camera would offer better utility. Notwithstanding the fact that a PCD may not be well-suited for a particular image capture application, the PCD may still be valuable for viewing, editing, and/or sharing the images captured by a separate camera. There is therefore a need for a small, light-weight, durable, easy-to-use portable camera which can capture still images and videos and conveniently transfer them to a PCD to be displayed, edited, and/or shared.

### SUMMARY

In some embodiments, a camera system comprises: a portable camera; and a docking station for storing the portable camera, re-charging the portable camera, or transferring image data from the portable camera, wherein the portable camera can be removably coupled with the docking station with any of multiple different rotational orientations.

In some embodiments, a portable camera comprises: a unibody housing; a foldable printed circuit board assembly; and a battery, wherein the foldable printed circuit board assembly is folded at least partially around the battery.

In some embodiments, a method of assembling a portable camera comprises: providing a unibody housing, the unibody housing having one or more sidewalls and an open end; and inserting one or more components of the portable camera through the open end into the unibody housing.

In some embodiments, a docking station for a plurality of portable cameras comprises: a plurality of receptacles, each receptacle being configured to hold one of the plurality of cameras; and a plurality of electrical connectors, each electrical connector being provided in a corresponding one of the plurality of receptacles, each of the plurality of electrical connectors being configured to electrically connect one of the plurality of cameras to the docking station when the one of the plurality of cameras is inserted into the corresponding receptacle.

### BRIEF DESCRIPTION OF THE DRAWINGS

FIGS. 1A-1C illustrate an example embodiment of a camera system.

FIGS. 2A-2C illustrate another example embodiment of a camera system.

FIG. 3A illustrates an example embodiment of the camera described with respect to FIGS. 1A-2C.

FIG. 3B illustrates an example embodiment of the camera mounted to a pair of eyeglasses.

FIGS. 3C-3D illustrate an example embodiment of the docking station described above with respect to FIGS. 1A-2C.

FIG. 4A is a cross-sectional view of an example embodiment of the camera shown in FIG. 3A.

FIG. 4B is an exploded view of an example embodiment of the camera shown in FIG. 3A.

FIGS. 4C-4F illustrate an example embodiment of the assembly of a light diffuser, a camera module, and a camera module retainer.

FIG. 4G illustrates an example embodiment of a printed circuit board assembly for the camera shown in FIG. 3A.

FIG. 4H illustrates an acoustic vent attached to an inner surface of the unibody housing of the camera.

FIGS. 4I and 4J illustrate a technique for using a shim to prevent interference with the acoustic vent when inserting the internal components of the camera through the open end of the housing.

FIG. 5 is an exploded view of an example embodiment of the docking station shown in FIG. 3C.

FIG. 6A is a rear perspective view of the camera, which illustrates an example embodiment of concentric ring electrical contacts for connecting the camera with the docking station.

FIG. 6B illustrates an example embodiment of radially-arranged electrical contacts for connecting the docking station with the concentric ring electrical contacts of the camera.

FIG. 6C illustrates an example embodiment of the camera receptacles in the docking station.

### DETAILED DESCRIPTION

This disclosure describes a portable camera system which can wirelessly transmit data to a portable computing device, such as a smartphone or tablet. The camera system may include a camera and a docking station. The camera may have volume smaller than, for example, three cubic inches and may include an electrical coupler, a secondary battery, lens, image sensor, circuit board, and microphone. The camera may be configured to generate image data (e.g., still images and/or video) using the image sensor and/or microphone. The docking station may have volume smaller than, for example, twenty cubic inches and may include a primary battery, an electrical input, and a camera receptacle. The electrical input may be configured to receive a direct current to charge the primary battery, and the battery receptacle may include both a physical camera receptacle and an electrical camera coupler.

The camera system may have a coupled state in which the camera is disposed within the physical camera receptacle and there is an electrical coupling between the electrical coupler of the camera and the electrical camera coupler of the docking station. The system may also have a separated state in which the camera is physically separate or independent of the docking station.

A portable computer device may be used to wirelessly receive the image data generated by the camera. In some embodiments, the camera may include a wireless communication module configured to wirelessly transmit the image data to the portable computer device. In some embodiments, the docking station may be configured to receive the image data from the camera while in the coupled state and then wirelessly transmit the image data to the portable computer device via a wireless communication module.

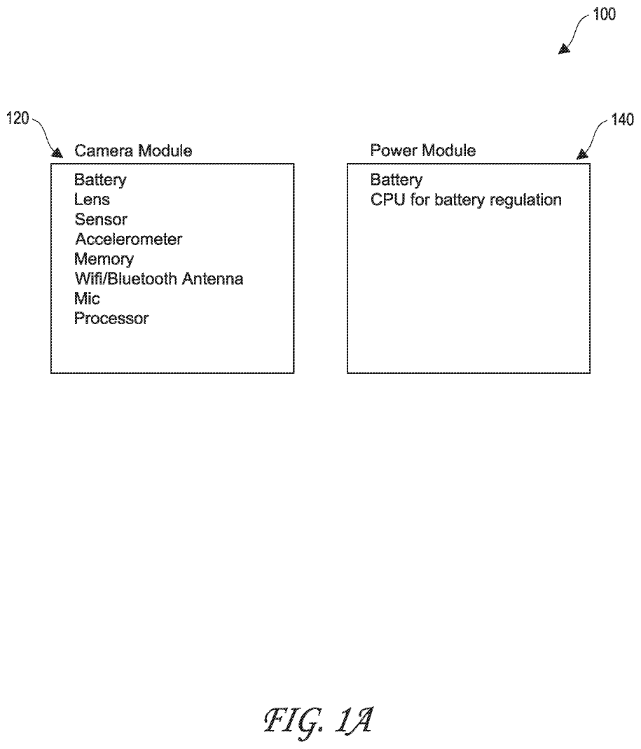

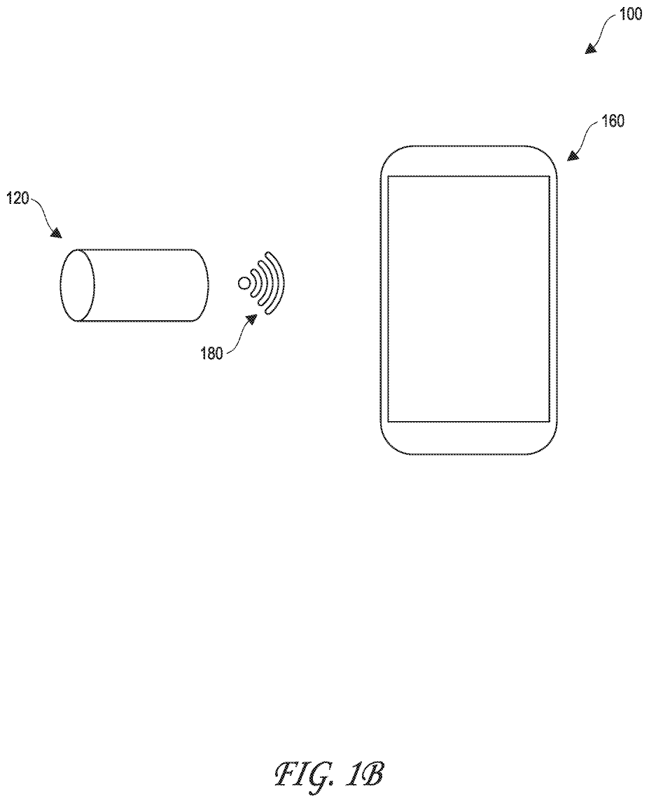

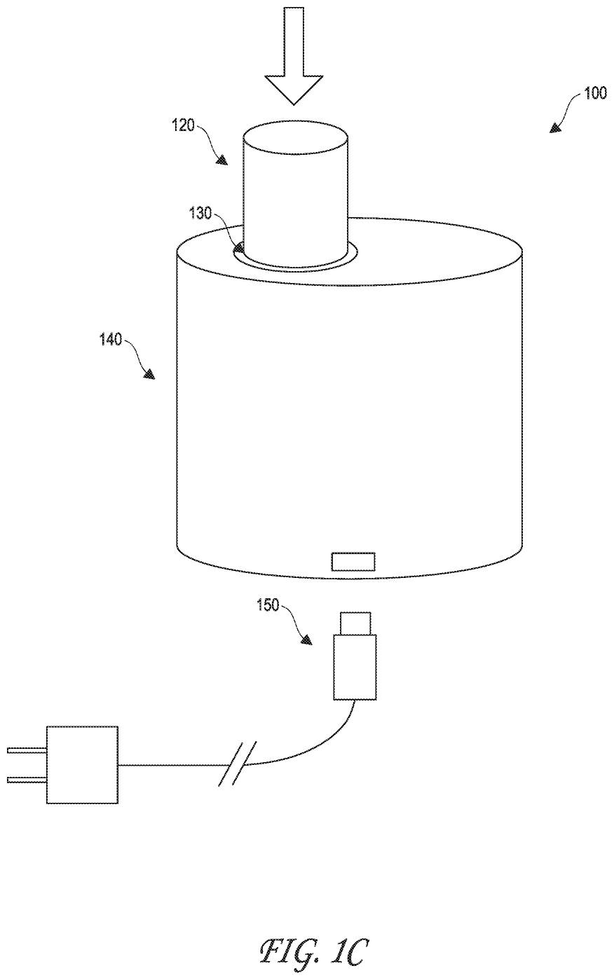

FIGS. 1A-1C illustrate an example embodiment of a camera system. The illustrated system 100 includes a portable computer device (PCD) 160, a camera 120, and docking station 140 (also referred to as a power module).

The portable computer device 160 may be any small portable computing device that includes integrated wireless data transfer functionalities, a power source, a display screen, and at least one user input device. In addition, a PCD is defined as having an external form factor smaller than, for example, twenty cubic inches. Examples of a PCD include but are not limited to a smartphone, mini-computer, e-reader, tablet, or tablet phone.

The camera 120 is an external unit which may have a form factor smaller than, for example, three cubic inches. In some embodiments, the camera 120 may include a battery, lens, image sensor, accelerometer, memory, antenna (for wireless communication using, for example, WiFi or Bluetooth protocol), microphone, and/or a processor, as shown in FIG. 1A. The components of the camera can capture audio data, image data (including still images and/or video), and/or positional data using the microphone, image sensor, and accelerometer, respectively. The camera 120 may further include an electrical coupler configured to engage with the docking station.

In the illustrated embodiment, the docking station 140 may include a battery and a CPU (central processing unit), as shown in FIG. 1A. The docking station 140 may further include a camera receptacle comprising an electrical camera coupler and a physical camera receptacle.

In a separated state (FIG. 1B), the camera 120 may be configured to wirelessly transmit data 180 to the PCD 160 (e.g., via Wi-Fi or Bluetooth connectivity). The wireless transmission of the data 180 may be continuous or intermittent depending on the mode of transmission. Various well known data transfer techniques may be incorporated such as buffering, packaging, indexing, encrypting, etc. In addition, the wireless data transfer 180 may include 2-way communication, enabling the PCD 160 to control or otherwise affect the data capture and/or transfer. For example, the PCD 160 may instruct the camera to wirelessly send only audio data while recording video and position data.

In a coupled state (FIG. 1C), the camera 120 is coupled with the docking station 140 via the camera receptacle 130. The coupling between the camera 120 and docking station 140 includes both an electrical coupling and a physical coupling. The electrical coupling includes an electrical coupling between the electrical coupler of the camera 120 and the electrical camera coupler of the docking station 140. The physical coupling includes a physical coupling of the camera 120 within the physical camera receptacle of the docking station 140.

In the illustrated embodiment, the physical camera receptacle is a recess configured to receive and support the camera 120. (While a cylindrical camera is illustrated, other shapes are also possible as disclosed further herein.) The physical coupling between the camera 120 and docking station 140 is also configured to engage the electrical coupling between the camera 120 and the docking station 140. For example, the camera 120 electrical coupler may be disposed on the illustrated bottom end, and the docking station camera electrical coupler may be disposed on the interior bottom of the cylindrical recess. Therefore, the positioning of the camera 120 within the recess of the docking station 140 will automatically engage the electrical coupling therebetween.

The docking station 140 further includes an electrical input 150 through which the docking station's battery may be charged. The electrical input 150 may be any type of electrical coupler such as a USB, mini USB, micro USB, etc. A user may selectively charge the docking station's battery by connecting the electrical input 150 to a power source such as an AC outlet or DC power supply (e.g., a USB power outlet).

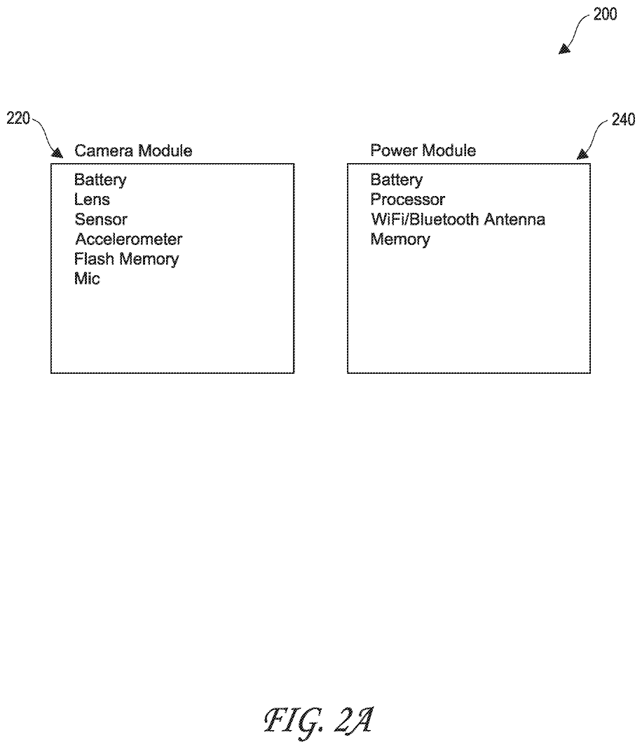

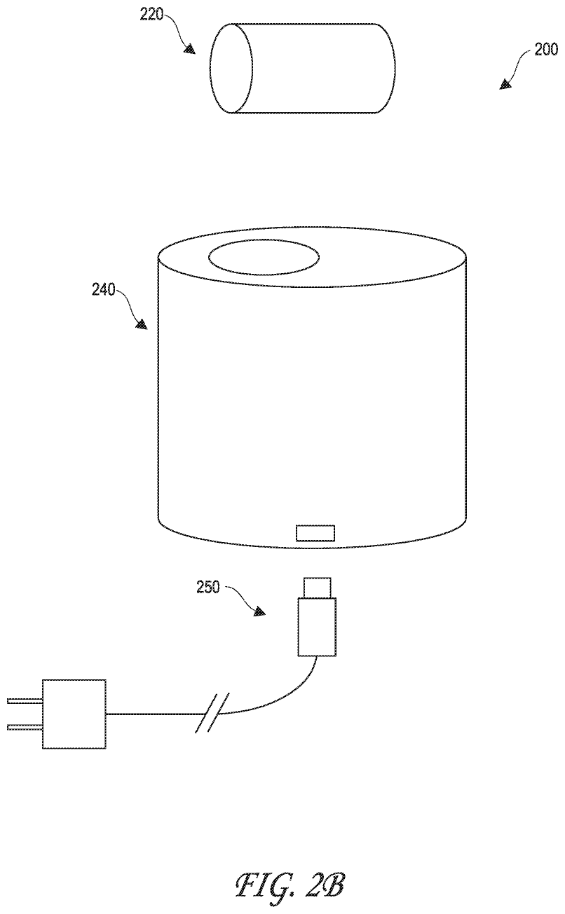

FIGS. 2A-2C illustrate another example embodiment of a camera system. The illustrated system 200 also includes a portable computer device (PCD) 260, a camera 220, and docking station 260.

The portable computer device 260 may be any small portable computing device that includes integrated wireless data transfer functionalities, a power source, a display screen, and at least one user input device. In addition, a PCD is defined as having an external form factor smaller than, for example, twenty cubic inches. Examples of a PCD include but are not limited to a smartphone, mini-computer, e-reader, tablet, or tablet phone.

The camera 220 is an external unit which may have a form factor smaller than, for example, three cubic inches. In the illustrated embodiment, the camera 220 may include a battery, lens, image sensor, accelerometer, memory, and microphone, as shown in FIG. 2A. The components of the camera are configured to capture audio data, image data (including still images and/or video), and position data from the microphone, image sensor, and accelerometer, respectively. The camera 220 may further include an electrical coupler configured to engage with the docking station 240.

In the illustrated embodiment, the docking station 240 may include a battery, processor, antenna (for wireless communication using, for example, WiFi or Bluetooth protocol), and memory as shown in FIG. 2A. The docking station 240 may further include a camera receptacle comprising an electrical camera coupler and a physical camera receptacle.

In a separated state (FIG. 2B), the camera 220 may be configured to independently capture and store image and audio data. The camera 220 may include one or more buttons to allow a user to control the image and audio data capture and storage using the camera 220. For example, a user may be able to selectively engage/disengage the capture and recording of audio, video, and/or position data by pressing one or more buttons located externally on the camera (not shown). In addition, the camera 220 may utilize one or more sensors to control parameters. For example, an accelerometer may be used to correlate movement of the camera 220 (e.g., in response to a tap or double tap on the camera by the user) with an activation of the capture and recording of audio, video, and/or position data.

In the separated state, the docking station 240 may be electrically connected to an external power source via an electrical input 250. The docking station 240 further includes an electrical input 250 through which the docking station's battery may be charged. The electrical input 250 may be any type of electrical coupler such as a USB, mini USB, micro USB, etc. A user may selectively charge the docking station's battery by connecting the electrical input 250 to a power source such as an AC outlet or DC power supply (e.g., USB power outlet).

In a coupled state (FIG. 2C), the camera 220 is coupled with the docking station 240 via the camera receptacle 230. The coupling between the camera 220 and docking station 240 includes both an electrical coupling and a physical coupling. The electrical coupling includes an electrical coupling between the electrical coupler of the camera 220 and the electrical camera coupler of the docking station 240. The physical coupling includes a physical coupling of the camera 220 within the physical camera receptacle of the docking station 240. In the illustrated embodiment, the physical camera receptacle is a recess configured to receive and support the camera 220. (While a cylindrical camera is illustrated, other shapes are also possible as disclosed further herein.) It will be appreciated that the physical coupling between the camera 220 and docking station 240 is also configured to engage the electrical coupling between the camera 220 and the docking station 240. For example, the camera 220 electrical coupler may be disposed on the illustrated bottom end and the docking station camera electrical coupler may be disposed on the interior bottom of the cylindrical recess. Therefore, the positioning of the camera 220 within the recess of the docking station 240 will automatically engage the electrical coupling therebetween.

Unlike the embodiment illustrated in FIGS. 1A-1C, the electrical coupling between the camera 220 and the docking station 240 also causes the camera to transfer data from the camera 220 memory to the docking station 240. The docking station 240 may then wirelessly transmit 280 the data to the PCD 260. The docking station 240 may optionally be configured to also record the data on the docking station's 240 memory. It will be appreciated that the wireless transmission 280 between the docking station 240 and the PCD 260 may be two-way or one-way. A two-way wireless communication may include the ability for the PCD 260 to control or otherwise alter the functionality of the camera 220 and/or the docking station 240.

Some embodiments of the camera may incorporate processing of a raw video stream as captured by the image sensor. The steps may include demosiacing, color correction, gamma correction, local contrast enhancement, noise filtering, and sharpening. Video compression may be employed prior to saving the video stream to storage. Video processing and compression are typically the most power intensive operations for a video camera. In order to save power in the camera, and thus reduce its size, some or all of the processing and compression may be moved to the docking station or the PCD. In some embodiments, the camera only stores raw image sensor data and the docking station and/or the PCD perform all the video processing and compression. Alternatively, the camera may perform only preliminary processing and compression. For example, the camera may only process motion JPEG to eliminate the need for a DRAM chip on the camera. In this scenario, the docking station and/or the PCD may perform the secondary processing and compression such as completing the compression of the stream. Alternatively, the camera may perform the majority of the processing and compressing while some minor final processing such as Electronic Image Stabilization (EIS) is performed by the docking station and/or PCD.

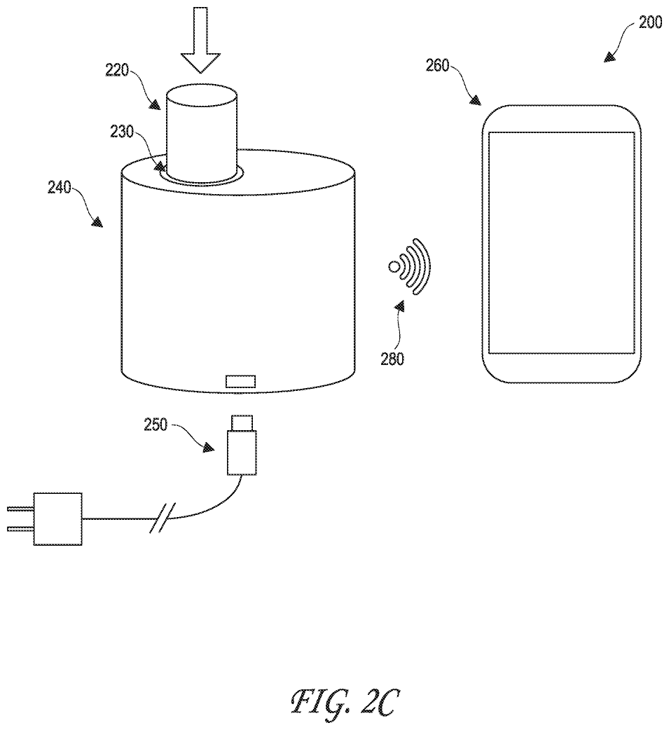

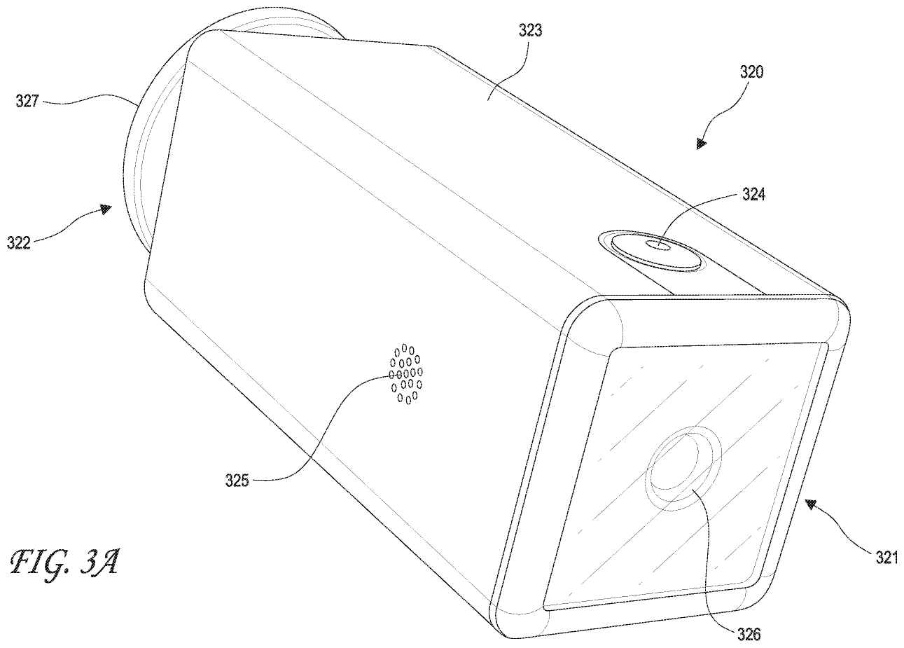

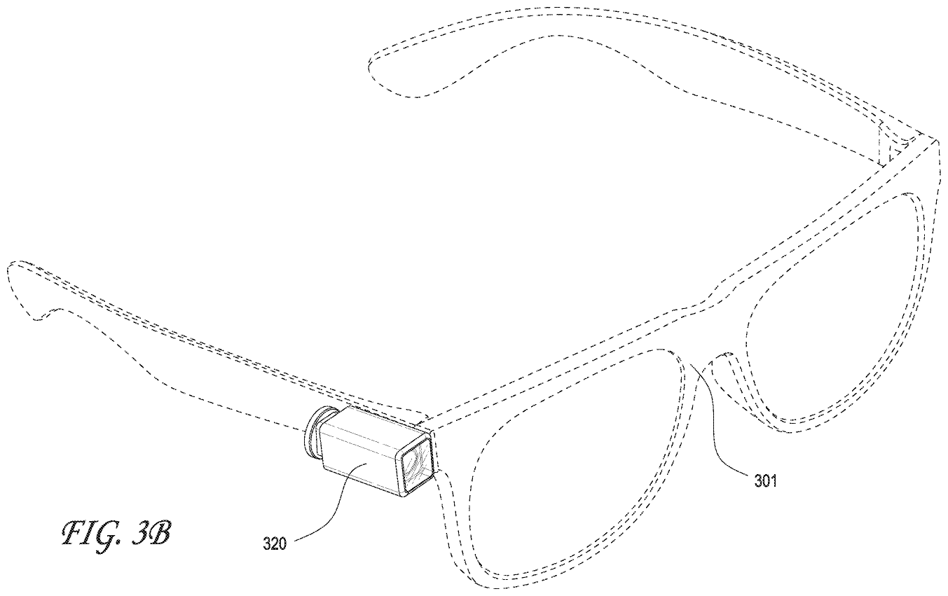

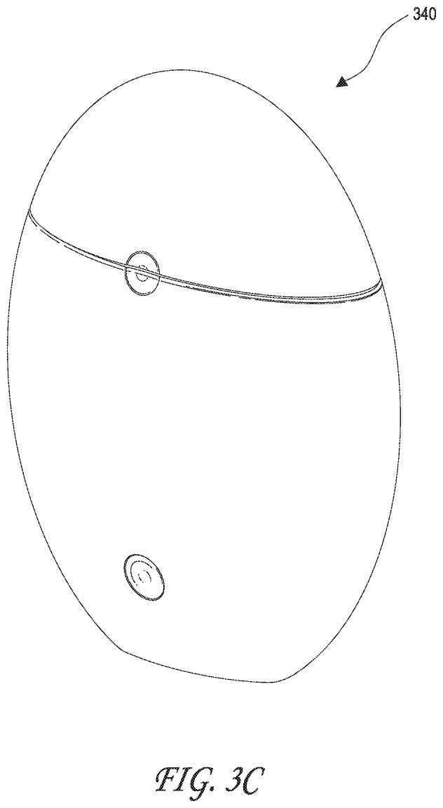

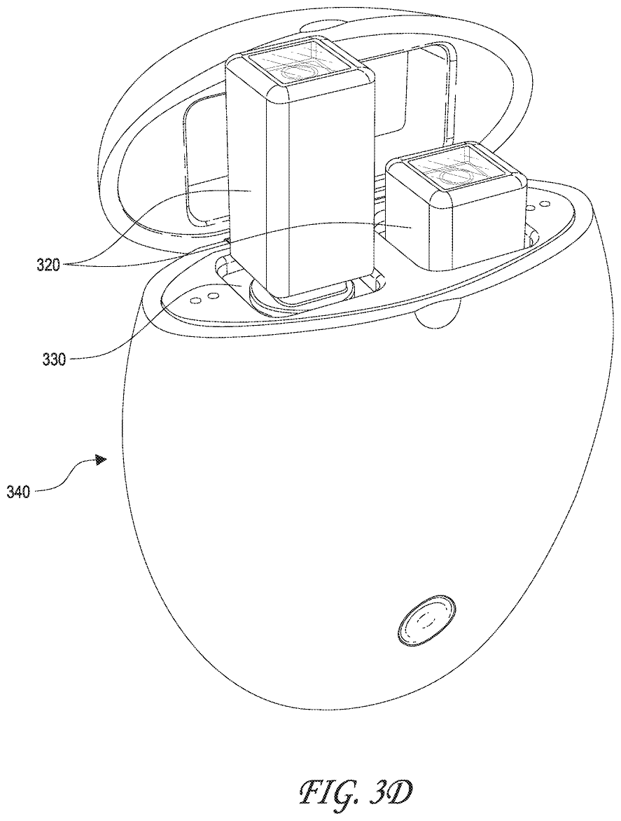

FIG. 3A illustrates an example embodiment 320 of the camera described above with respect to FIGS. 1A-2C. The illustrated embodiment of the camera 320 has a unibody housing 323. The housing 323 has a main compartment that houses the majority of internal components. In the illustrated embodiment, the main compartment is a straight-walled tube with a substantially square cross-section (with rounded corners), though other cross-sectional shapes can also be used. In some embodiments, the tube is only open to its full width at one end, so the straight sidewalls of the housing 323 can facilitate the sliding insertion of the interior components at the open end. The housing 323 can be made of metal, such as aluminum, though other materials can also be used. The housing 323 can include one or more holes 325 to allow for entry of air pressure waves for capturing audio using an internal microphone.

The camera 320 has a front end 321 and a rear end 322. The front end 321 includes a camera aperture 326 to allow light in. The rear end 322 includes a circular flange 327. As described further herein, the circular flange 327 can mechanically couple with one or more connectors inside the camera receptacle in the docking station so as to removably secure the camera 320 in the receptacle. The fact that the circular flange 327 is round means that the camera 320 can be inserted into the receptacle in the docking station with any rotational orientation and still mechanically connect with the connectors inside the receptacle. This feature therefore increases ease-of-use because the user does not need to ensure any particular rotational orientation when inserting the camera 320 into the receptacle in the docking station.

The camera 320 also includes one or more user interface elements, such as the button 324. The button 324 can be used to perform one or more control functions, such as initiating and/or stopping image capture by the camera 320. Although a mechanical button 324 is illustrated, other types of user interface elements can also be used, such as switches, capacitive buttons, etc.

FIG. 3B illustrates an example embodiment of the camera 320 mounted to a pair of eyeglasses 301. This allows the user to capture still images and/or video from his or her point of view. In some embodiments, the camera 320 is configured to magnetically couple with the eyeglasses 301. The camera 320 can be magnetically mounted to the eyeglasses 301 using the techniques disclosed in U.S. Patent Publication 2018/0295264, the entirety of which is hereby incorporated by reference herein. The camera 320 can also be attached to other mounts, as disclosed in U.S. patent application Ser. No. 16/265,213 (published as US2019/0235356) and in U.S. patent application Ser. No. 16/681,021 (published as ####/#######), the entire contents of which are hereby incorporated by reference herein.

FIGS. 3C-3D illustrate an example embodiment of the docking station 340. FIG. 3C shows the docking station 340 in the closed configuration, while FIG. 3D shows the docking station in the open configuration. As shown in FIG. 3D, the docking station 340 can include one or more camera receptacles 330. One or more instances of the camera 320 can be inserted into the camera receptacles 330 for storage, battery charging, and/or image data transfer. The fact that docking station 340 can hold multiple instances of the camera 320 allows the user to still have access to one camera 320 while the other may be charging, downloading image data, etc.

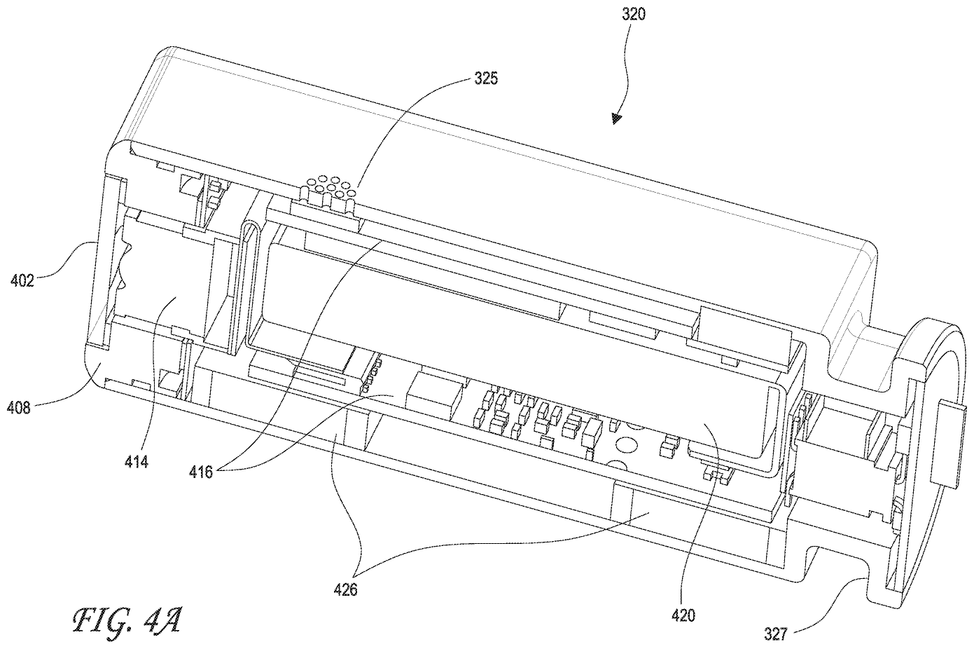

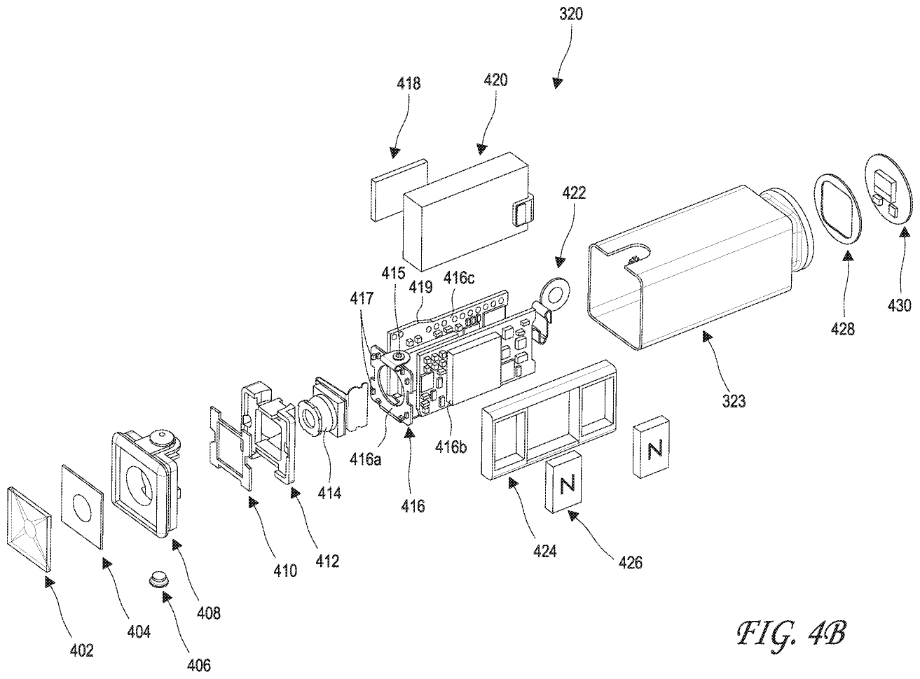

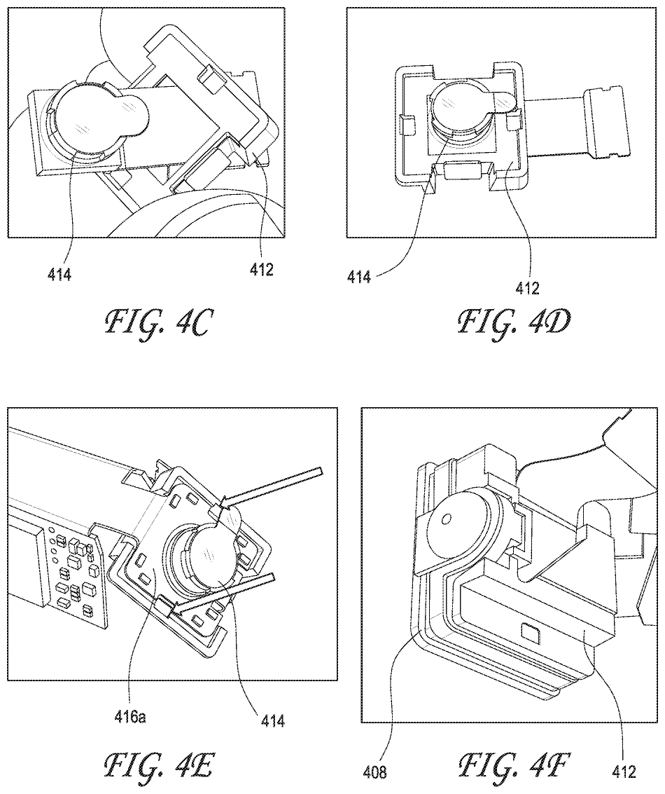

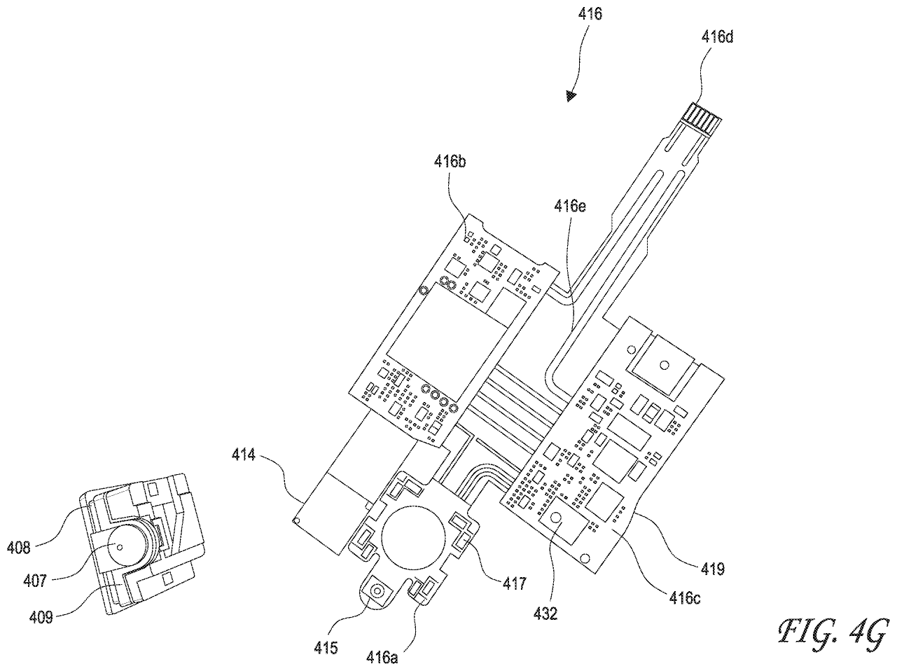

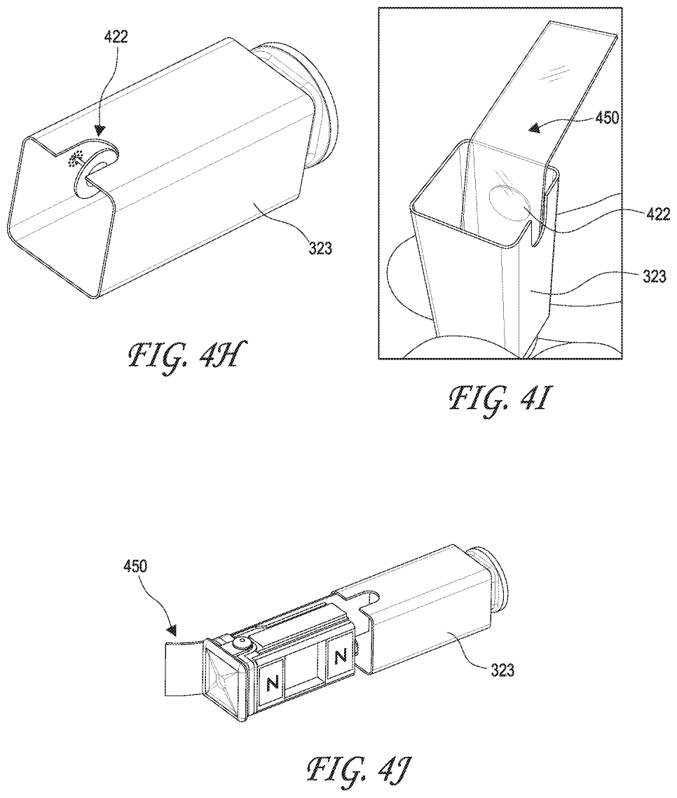

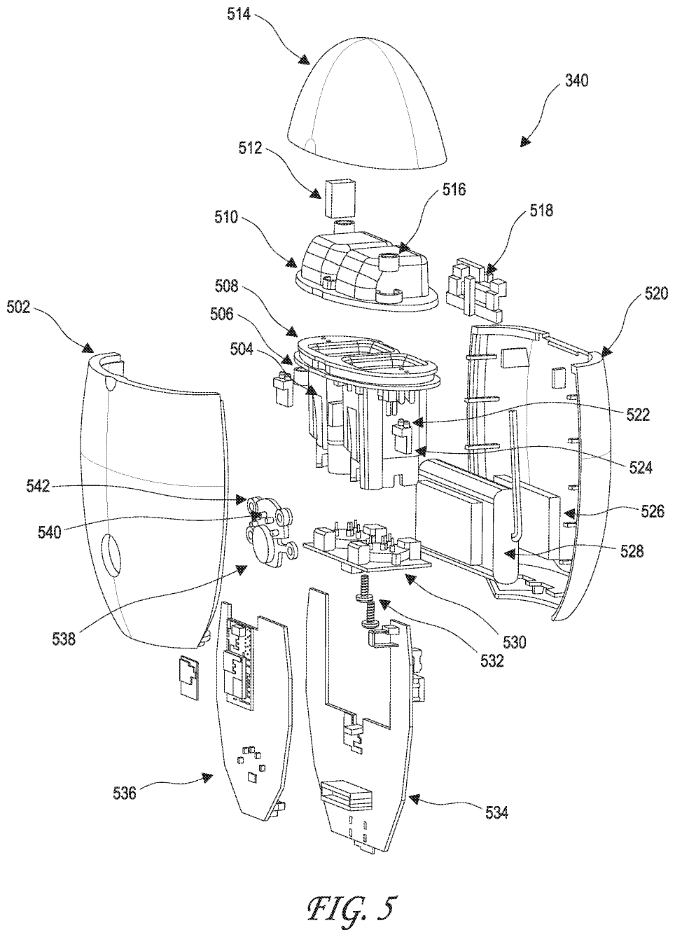

FIG. 4A is a cross-sectional view of an example embodiment of the camera 320 shown in FIG. 3A. The camera 320 includes a camera module 414 provided behind a protective cover glass 402. The camera module 414 can include one or more lenses and an image sensor.

The camera 320 also includes a light diffuser 408. The light diffuser 408 forms an illuminating ring around the aperture of the camera 320. The light diffuser 408 can be lit up, for example, while the camera module 414 is collecting image data. This illuminated ring around the camera aperture can serve as an indicator to the user and other observers that the camera module 414 is recording.

The camera 320 also includes a printed circuit board assembly 416 with electrical components, such as a processor, memory, a microphone, an accelerometer, etc. As discussed further herein, the printed circuit board assembly 416 can be foldable and can be made up of various rigid sections and flexible connecting sections. Two magnets 426 are shown adjacent to the printed circuit board assembly 416. The magnets 426 can be provided inside the camera 320 for magnetically attaching it to a camera mount, as shown in FIG. 3B.

FIG. 4B is an exploded view of an example embodiment of the camera 320 shown in FIG. 3A. The exploded view shows the unibody housing 323 of the camera 320 and all of the interior components extracted therefrom.

Beginning on the left, the exploded view shows the cover glass 402 and the light diffuser 408. The cover glass 402 can be made of, for example, sapphire, glass, polycarbonate, or other optical materials. Retainer tape 404 can be used to secure the cover glass 402 to the front surface of the light diffuser 408. The cover glass 402, the retainer tape 404, and the light diffuser 408 all include a central aperture to allow light to pass through to the camera module 414.

As mentioned above, the light diffuser 408 forms an illuminating ring around the aperture of the camera 320. The light diffuser 408 is illuminated from behind by one or more light sources, such as one or more light emitting diodes (LEDs) 417, provided on a front section 416a of the printed circuit board assembly 416. The light diffuser 408 can be made of a translucent optical material, such as polycarbonate, which diffuses the light from the LEDs 417 throughout the light diffuser 408.

In some embodiments, the light diffuser 408 has an integrated rubber button boot 407 which covers and forms a protective seal for a button switch 415 on the front section 416a of the printed circuit board assembly 416. A button actuator 406 can be provided inside the rubber button boot 407—in contact with the button switch 415—so as to transfer force applied to the exterior of the rubber button boot 407 to the button switch 415. The light diffuser 408 can also include an integrated rubber ring 409 that goes around the perimeter of the light diffuser. The rubber ring 409 and the rubber button boot 407 provide a protective seal when the light diffuser 408 is inserted into the open end of the unibody housing 323. The rubber button boot 407 and the rubber ring 409 can be formed in place on the light diffuser 408 using, for example, an overmolding process.

The exploded view in FIG. 4B also shows the camera module 414 and a camera module retainer 412. The camera module 414 can be secured between the backside of the light diffuser 408 and the front side of the camera module retainer 412. FIGS. 4C-4F illustrate an example embodiment of the assembly of the light diffuser 408, the camera module 414, and the camera module retainer 412. FIG. 4C shows the camera module 414 and the camera module retainer 412. As illustrated, the camera module 414 includes a ribbon cable. The ribbon cable can be passed through a hole in the camera module retainer 412 and then connected to the printed circuit board assembly 416. FIG. 4D shows the camera module 414 in position on the flat mounting surface of the camera module retainer 412. As best seen in FIG. 4C, in the illustrated embodiment the hole for the ribbon cable of the camera module 414 is a triangular hole through the mounting surface of the camera module retainer 412.

Once the camera module 414 is mounted in place on the camera module retainer 412, the front section 416a of the printed circuit board assembly 416—which includes the LEDs 417—can be folded into place in front of the camera module 414. This is shown in FIG. 4E. As illustrated, the front section 416a of the printed circuit board assembly 416 can include a central aperture through which the lens barrel of the camera module 414 can extend. The front section 416a of the printed circuit board assembly 416 can be attached to the front side of the camera module retainer 412 by retainer tape 410.

Once the camera module 414 and the front section 416a of the printed circuit board assembly 416 are in position, the light diffuser 408 and the camera module retainer 412 can be joined together—with the front section 416a of the circuit board 416 sandwiched in between—by one or more connectors. This is shown in FIG. 4F. In some embodiments, for example, the light diffuser 408 includes one or more flexible connecting arms projecting from its back side. These connecting arms can be inserted into corresponding holes (shown by the arrows in FIG. 4E) in the camera module retainer 412 to securely hold the camera module 414 and the front section 416a of the printed circuit board assembly 416, with LEDs 417 provided thereon, in position.

The front section 416a of the printed circuit board assembly 416 includes a foldable tab upon which the button switch 415 is mounted. When the light diffuser 408—which includes the integrated rubber button boot 407—is joined with the camera module retainer 412, the foldable tab of the front section 416a of the printed circuit board assembly 416 is bent so that the button switch 415 is located under the rubber button boot 407.

FIG. 4G illustrates an example embodiment of a printed circuit board assembly 416 for the camera 320 shown in FIG. 3A. In some embodiments, the printed circuit board assembly 416 is foldable so as to efficiently use space within the unibody housing 323. For example, the printed circuit board assembly 416 can include two or more rigid sections connected together by one or more flexible sections. The illustrated embodiment of the printed circuit board assembly 416 includes multiple rigid sections 416a-d joined together by a flexible central section 416e. In the illustrated embodiment, the printed circuit board assembly 416 can be folded around at least two opposing sides of the battery 420. As shown in FIG. 4B, the battery 420 is box-shaped and the printed circuit board assembly 416 is folded such that the rigid side sections 416b, 416c are adjacent to opposing faces of the battery and the flexible section 416e is adjacent to an edge of the battery. Thus, the printed circuit board assembly 416 is foldable to form a U-shape cross-section and the battery 420 can be provided in the space at the center of the U-shaped folded circuit board. This configuration makes efficient use of the available space within the unibody 323 of the camera 320. In some embodiments, a foam spacer 418 can also be provided in the center portion of the folded U-shaped printed circuit board assembly 416.

The camera 320 can also include a magnet holder 424 which holds one or more magnets 426. As already discussed, the magnets 426 can be used to magnetically attach the camera 320 to one or more mounts, such as a magnetic mount on the eyeglasses 301 shown in FIG. 3B.

With reference back to the exploded view in FIG. 4B, a back printed circuit board assembly 430 is shown. The back printed circuit board assembly 430 can be attached flush with the rear of the circular flange 327 of the camera 320 by retainer tape 428. As described further herein, the outer surface of the back printed circuit board assembly 430 can include one or more electrical contacts. These electrical contacts can be used to make electrical connections with the docking station 340 when the camera 320 is inserted into the receptacle 330 inside the docking station. The electrical contacts of the back printed circuit board assembly 430 can be electrically connected to the components of the camera 320 via the rear section 416d of the printed circuit board assembly 416 shown in FIG. 4G.

As already discussed, the housing 323 of the camera 320 can be a unibody case (e.g., without seams or separate parts that need to be assembled). The unibody housing 323 is advantageous for its strength. However, the unibody housing 323 can complicate assembly of the camera 320 because it can make access difficult for inserting and positioning components inside the housing. For example, it may be more difficult to insert interior components with the proper alignment when access to the housing is only possible through an open end of the housing. This can be particularly true for embodiments of the camera 320 which are designed to be water resistant or waterproof because this can necessitate fine alignment between various parts, such as an acoustic vent, inside the unibody housing 323. FIGS. 4H-4I illustrate an example technique for overcoming such difficulties.

FIG. 4H illustrates an acoustic vent 422 attached to an inner surface of the unibody housing 323 of the camera 320. The acoustic vent 422 is attached to the housing 323 in alignment with the holes 325 which are provided to allow sound waves to pass through and be captured by a built-in microphone mounted on the printed circuit board assembly 416. The acoustic vent 422 can be, for example, a woven material that is specially designed to transmit air and sound while substantially blocking dust and liquids. In order to prevent intrusion of dust or liquids, the acoustic vent 422 needs to be properly aligned with the holes 325 in the housing 323 of the camera 320. Due to limited access, such alignment would be difficult to accomplish after having already inserted other interior components of the camera 320. However, insertion of the other interior components of the camera 320 after aligning and adhering the acoustic vent 422 would run the risk of damaging or peeling back the acoustic vent. This difficulty can be overcome using the shim 450 shown in FIG. 4I.

FIGS. 4I and 4J illustrate a technique for using a shim 450 to prevent interference with the acoustic vent when inserting the internal components of the camera 320 through the open end of the housing 323. During assembly of the camera 320, the acoustic vent 422 can be adhered to the inner wall of the housing 323 before other components of the camera 320 have been inserted, as shown in FIG. 4H. This allows the acoustic vent 422 to be properly aligned and applied to the housing wall without other interior components being in the way. Then, as shown in FIG. 4I, a thin shim 450 can be inserted into the housing 323 against the surface where the acoustic vent 422 is located. The assembled components of the camera 320 can then be slidably inserted into the housing 323 at its open end. This is shown in FIG. 4J. The shim 450 acts as a barrier and prevents the acoustic vent 422 from being damaged or partially peeled back from the interior surface of the housing 323 as the other components are inserted. Once all of the other components of the camera 420 have been inserted, the shim 450 can be removed.

A built-in microphone 432 can be provided on the printed circuit board assembly 416 such that it is directly adjacent to the acoustic vent 422 in the assembled configuration. This is shown in FIG. 4G. In the illustrated embodiment, the microphone 432 is mounted on side section 416c of the printed circuit board assembly 416. In some embodiments, a gasket can be provided around the periphery of the microphone between the printed circuit board 416c and the acoustic vent 422. To assist with proper alignment between the acoustic vent and the built-in microphone 432, the side section 416c of the printed circuit board assembly 416—where the microphone is located—can include a ramp feature 419 where the width of the circuit board 416c increases from a size smaller than the interior dimension of the housing 323 to a size substantially equal to the interior dimension of the housing.

The width of the circuit board 416c is smaller than the interior dimension of the housing 323 at the end which is inserted first into the housing. This allows for easy insertion of the assembled interior components of the camera 320. However, at the end of the circuit board 416c which is nearer to the open end of the housing 323—and which therefore enters the housing last during insertion—the width of the circuit board 416c ramps up to the full interior width of the housing, thus allowing for an interference fit between the housing and the ramp feature of the circuit board 416c. This ramp feature 419 causes the microphone 432 to be brought into lateral alignment with the acoustic vent 422 as the assembly of interior components is inserted into the housing 323 and the ramp feature enters into an interference fit with the housing.

FIG. 5 is an exploded view of an example embodiment of the docking station 340 shown in FIG. 3C. The illustrated embodiment includes a front housing section 502, a rear housing section 520, and a cap 514. The cap 514 includes an inner cap 510, an upper magnetic latch 512, a magnet 516, and a hinge assembly 518. A battery 528 is mounted in the rear housing section 520 using foam tape 526. The battery 528 can be used to re-charge the camera 320 when it is plugged into the docking station 340. In some embodiments, a button 538 is used to initiate re-charging of the camera 320. The button 538 can include a light pipe 542 (and guide 540) that illuminates when the camera 320 is being charged by the docking station 340.

The docking station 340 also includes a camera receptacle 508 which is capable of holding two instances of the camera 320. The camera receptacle 508 includes a lower magnetic latch 504 and a magnet 506 which work in conjunction with the upper magnetic latch 512 in the cap 514. The camera receptacle 508 also includes a light pipe 522 (and guide 524) that illuminates when the camera 320 is charging. A printed circuit board assembly 530 plugs into the bottom of the camera receptacle 508. The printed circuit board assembly 530 includes a plurality of electrical contacts which are designed to connect with electrical contacts on the back of the camera 320 when the camera is plugged into the receptacle 508. In some embodiments, the electrical contacts on the printed circuit board assembly 530 are spring-loaded pins. Fasteners 532 are used to connect the printed circuit board assembly 530 to the bottom of the camera receptacle 508. The docking station 340 can also include additional printed circuit board assemblies 534, 536 to perform additional tasks such as image data processing and wireless communication to transfer image data to a portable computing device, such as a smartphone.

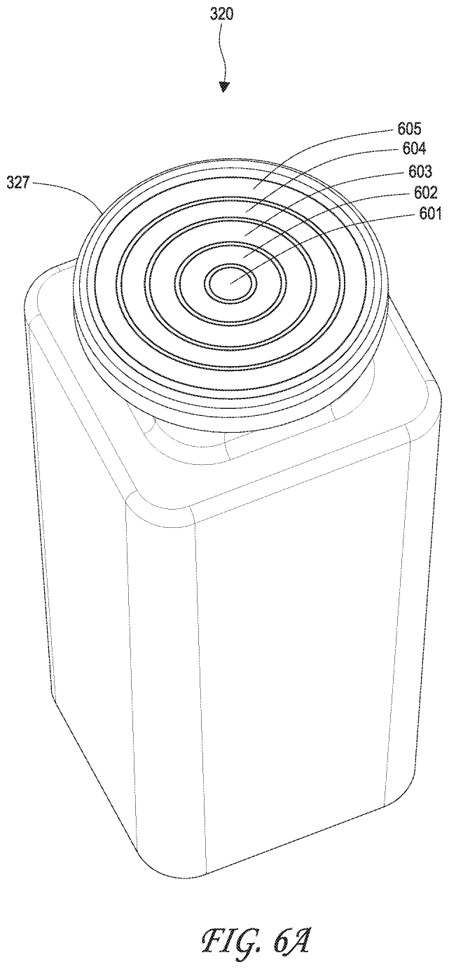

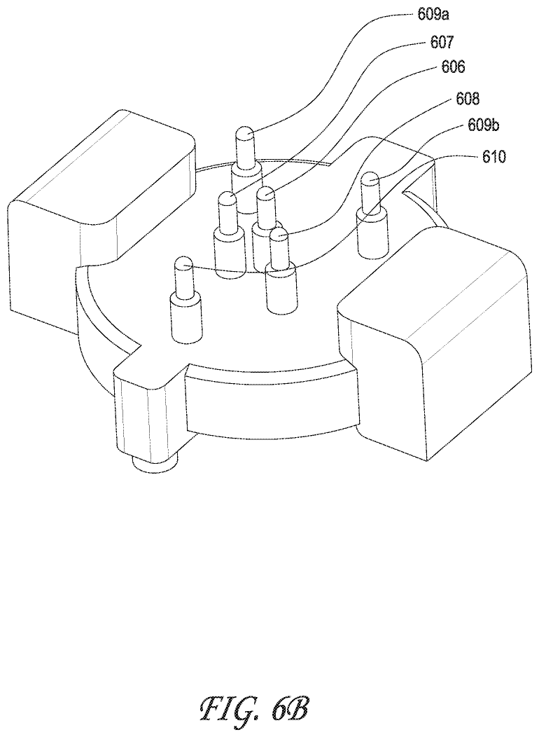

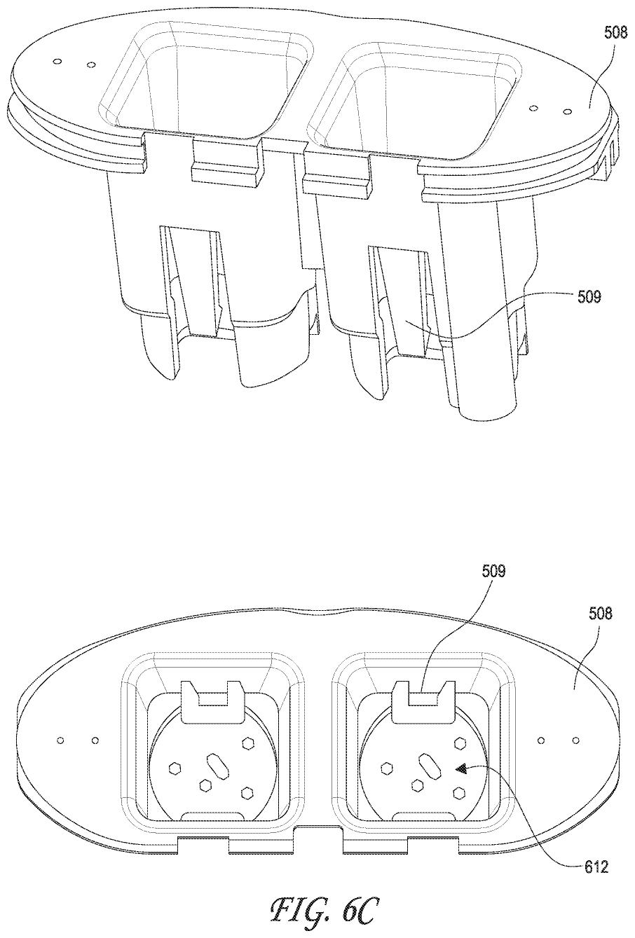

FIG. 6A is a rear perspective view of the camera 320, which illustrates an example embodiment of a set of concentric ring electrical contacts 601-605 for connecting the camera 320 with the docking station 340. The set of concentric ring electrical contacts 601-605 can be provided on the rear surface of the circular flange 327. For example, the set of concentric ring electrical contacts 601-605 can be formed on the outer surface of the back printed circuit board assembly 430 (see FIG. 4B).

The set of concentric ring electrical contacts includes a center conductor 601 and several ring-shaped conductors 602-605 of successively increasing radius which are concentric to the center conductor 601. As illustrated, the ring-shaped conductors 602-605 can be circular such that they are rotationally symmetric under any amount of rotation. This feature increases ease-of-use because the user does not need to ensure any particular rotational orientation when mating the camera 320 with the docking station 340.

The set of concentric ring electrical contacts 601-605 can be used to carry a variety of electrical signals between the camera 320 and the docking station 340. Examples of these signals include a power supply voltage, electrical ground, one or more image data transmission signals, a battery charging voltage, etc.

FIG. 6B illustrates an example embodiment of radially-arranged electrical contacts 606-610 for connecting the docking station 340 with the concentric ring electrical contacts 601-605 of the camera 320. The electrical contacts 606-610 can be provided in the bottom of the camera receptacle in the docking station 340.

In some embodiments, the electrical contacts in the docking station 340 are spring-loaded pins 606-610. The spring-loaded pins 606-610 electrically connect with the set of concentric ring electrical contacts 601-605 on the camera 320 when the camera is inserted into the receptacle 330 of the docking station 340. Each of the spring-loaded pins 606-610 is located at a certain radial distance from the center of the receptacle. The radial distance of each of the spring-loaded pins 606-610 corresponds to the radius of one of the conductors 601-605 on the camera 320. For example, the center pin 606 is located at a radial distance of zero from the center of the camera receptacle 330 and therefore contacts the center conductor 601 on the camera 320. Pin 607 is located at a radial distance of 1 unit and therefore contacts the first ring conductor 602. Pin 608 is located at a radial distance of 2 units and therefore contacts the second ring conductor 603. And so on for the remaining pins. Each of the pins can be located at any angular position so long as the pin is provided at the correct radial distance from the center of the camera receptacle 330. This design means that the correct electrical connection between a pin 606-610 in the docking station 340 and a conductor on the camera 320 can be ensured regardless of the rotational orientation of the camera in the docking station.

Although the conductors 601-605 on the back of the camera 305 are shown as being round, other rotationally-symmetric shapes are also possible. For example, the concentric rings could be squares, hexagons, octagons, or any other shape that is symmetric under certain discrete amounts of rotation. In such embodiments, the physical shape of the camera receptacle 330 in the docking station 340 can be designed (e.g., with the same shape) so as to only allow insertion of the camera at one of the discrete rotationally-symmetric orientations.

FIG. 6C illustrates an example embodiment of the camera receptacles 508 in the docking station 340. The top image is a side perspective view of the camera receptacles 508, while the bottom image is a top view. As is evident in the top view, the camera receptacles 508 have holes 612 formed in their respective bottom surfaces at locations which correspond to the connector pins 606-610. Thus, the connector pins can extend into the receptacles 508 from below.

The camera receptacles 508 also include connecting arms 509 with tabs that interlock with the flange 327 of the camera 320 when the camera is inserted into the receptacle. In this way, the camera 320 can be removably secured within the receptacle 508. While the camera 320 is illustrated with a circular flange 327, other rotationally-symmetric shapes can be used in other embodiments. For example, the flange 327 could have a shape such as a square, hexagon, or octagon that is symmetric under certain discrete amounts of rotation. In such embodiments, the physical shape of the camera receptacle 508 can be designed (e.g., with the same shape) so as to only allow insertion of the camera at one of the discrete rotationally-symmetric orientations.

### OTHER CONSIDERATIONS

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y and at least one of Z to each be present.

Various modifications to the implementations described in this disclosure may be readily apparent to those skilled in the art, including combinations in whole or in part of the embodiments described above, and the principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

1. A camera system comprising:
a portable camera; and
a docking station for storing the portable camera, re-charging the portable camera, or transferring image data from the portable camera,
wherein the portable camera can be removably coupled with the docking station with any of multiple different rotational orientations.

2. The camera system of claim 1, wherein the portable camera includes a rotationally-symmetric flange that removably couples with the docking station.

3. The camera system of claim 2, wherein the rotationally-symmetric flange is round.

4. The camera system of claim 1, wherein the camera includes an electrical connector that can electrically connect with the docking station with any of multiple different rotational orientations.

5. The camera system of claim 4, wherein the electrical connector includes a plurality of rotationally-symmetric conductors.

6. The camera system of claim 5, wherein the plurality of rotationally-symmetric conductors are a plurality of concentric conductive rings.

7. The camera system of claim 6, wherein the rings are round.

8. The camera system of claim 6, wherein the docking station includes a plurality of electrical pins, each of the plurality of electrical pins being located at a radial distance from a center point which corresponds with a radius of one of the plurality of concentric rings.

9. The camera system of claim 8, wherein the plurality of electrical pins are spring-loaded pins.

10. The camera system of claim 1, wherein the docking station includes a receptacle in which the camera can be at least partially inserted.

11. A portable camera comprising:
a unibody housing;
a foldable printed circuit board assembly; and
a battery,
wherein the foldable printed circuit board assembly is folded at least partially around the battery.

12. The camera system of claim 11, wherein the foldable circuit board assembly includes a plurality of rigid sections and one or more flexible sections.

13. The camera system of claim 12, wherein the foldable circuit board assembly has a U-shaped cross-section.

14. The camera system of claim 13, wherein the battery is located in the open area of the U-shaped cross-section.

15. The camera system of claim 11, wherein the unibody housing comprises aluminum.

16. The camera system of claim 11, further comprising:
a light diffuser; and
one or more light sources to illuminate the light diffuser,
wherein the light diffuser forms an illuminating ring around an aperture of the camera.

17. The camera system of claim 16, wherein the light diffuser includes an integrated rubber ring that forms a seal between the light diffuser and an opening of the unibody housing.

18. The camera system of claim 11, wherein the unibody housing comprises a straight-walled tube.

19. The camera system of claim 11, wherein the camera comprises a magnetic mount.

20. The camera system of claim 11, wherein the camera comprises a flange for connecting the camera to a docking station.

21-30. (canceled)
